(19) United States
(12) Patent Application Publication
(10) Pub. No.: US 2015/0171260 A1
(43) Pub. Date: Jun. 18, 2015

(54) Low Resistivity Nitrogen-Doped Zinc Telluride and Methods for Forming the Same

(71) Applicant: Intermolecular Inc., San Jose, CA (US)

(72) Inventors: Wei Liu, Sunnyvale, CA (US); Amir Bayati, San Jose, CA (US); Zhi-Wen Wen Sun, Sunnyvale, CA (US)

(73) Assignee: Intermolecular Inc., San Jose, CA (US)

(21) Appl. No.: 14/108,697

(22) Filed: Dec. 17, 2013

(51) Int. Cl. H01L 31/18; H01L 31/0224

(52) U.S. Cl. CPC H01L 31/1828; H01L 31/1884; H01L 31/022425

(57) ABSTRACT

Embodiments provided herein describe methods for forming nitrogen-doped zinc telluride, such as for use in photovoltaic devices. The zinc telluride layer is formed using physical vapor deposition (PVD) at a processing temperature of between about 100° C. and about 450° C. in a gaseous environment that includes between about 3% and about 10% by volume of nitrogen gas.

### TECHNICAL FIELD

The present invention relates to zinc telluride. More particularly, this invention relates to nitrogen-doped zinc telluride, perhaps used in photovoltaic devices, and methods for forming such zinc telluride.

### BACKGROUND

Photovoltaic devices (or cells) are often formed by forming or depositing a light-absorbing layer, along with various other layers, onto a transparent (e.g., glass substrate). In recent years, cadmium telluride has become one of the materials used in the light-absorbing layers. Among the other layers formed are a front contact (or front contact layer) (e.g., a transparent conductive oxide), typically formed between the substrate and the light absorbing layer, and a back contact, typically formed on a side of the light-absorbing layer opposite the substrate.

One material that may be used in the back contact is zinc telluride. However, in order provide desirably performance (e.g., with respect to resistivity), the zinc telluride may need to be doped, such as with copper. One problem associated with the use of copper as the dopant is that copper is highly mobile and may move towards the front junction of the device, which may result in long-term stability and reliability issues when the device is used in the field.

The use of other dopants, including nitrogen, has been attempted. However, the doping techniques previously used (e.g., molecular-beam-epitaxy (MBE) doping) are very expensive and can not readily be scaled for high volume manufacturing.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 is a cross-sectional side view of a photovoltaic device according to some embodiments.

FIG. 2 is a graph depicting the resistivity of zinc telluride formed according to some embodiments.

FIG. 3 is a graph depicting the sheet resistance of zinc telluride formed according to some embodiments.

FIG. 4 is a graph depicting the current-voltage dependence of zinc telluride formed according to some embodiments.

FIG. 5 is a simplified cross-sectional diagram illustrating a physical vapor deposition (PVD) tool according to some embodiments.

FIG. 6 is a flow chart illustrating a method for forming a photovoltaic device according to some embodiments.

### DETAILED DESCRIPTION

A detailed description of one or more embodiments is provided below along with accompanying figures. The detailed description is provided in connection with such embodiments, but is not limited to any particular example. The scope is limited only by the claims, and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

The term “horizontal” as used herein will be understood to be defined as a plane parallel to the plane or surface of the substrate, regardless of the orientation of the substrate. The term “vertical” will refer to a direction perpendicular to the horizontal as previously defined. Terms such as “above”, “below”, “bottom”, “top”, “side” (e.g. sidewall), “higher”, “lower”, “upper”, “over”, and “under”, are defined with respect to the horizontal plane. The term “on” means there is direct contact between the elements. The term “above” will allow for intervening elements.

In some embodiments, nitrogen-doped zinc telluride is formed using physical vapor deposition (PVD) (e.g., sputtering) under particular processing conditions. In some embodiments, the deposition is performed at a temperature of between about 100° C. and about 450° C. Preferably, the temperature is between about 200° C. and about 400° C. More preferably, the temperature is between about 250° C. and about 375° C.

In some embodiments, the nitrogen-doped zinc telluride is formed using PVD in a gaseous environment that has a nitrogen concentration (i.e., volume percentage of nitrogen) of between about 3% and about 10%. Preferably, the nitrogen concentration is between about 3% and about 9%. More preferable, the nitrogen concentration is between about 4% and about 8%.

Experimental data indicates that nitrogen-doped zinc telluride formed in such a manner provides suitably low resistivity (and/or high carrier concentration) for use as a back contact in cadmium telluride-based photovoltaic devices. Additionally, because copper is not used as the dopant, back contacts using the nitrogen-doped zinc telluride may provide improved long-term stability and reliability (i.e., when compared to those using copper as the dopant).

However, it should be understood that although the methods described below may utilize the nitrogen-doped zinc telluride in a photovoltaic device (e.g., being formed above a transparent substrate and a light-absorbing layer) in some embodiments, the nitrogen-doped zinc telluride may be used in other devices or systems, and as such, may be formed above any material(s) suitable for various uses.

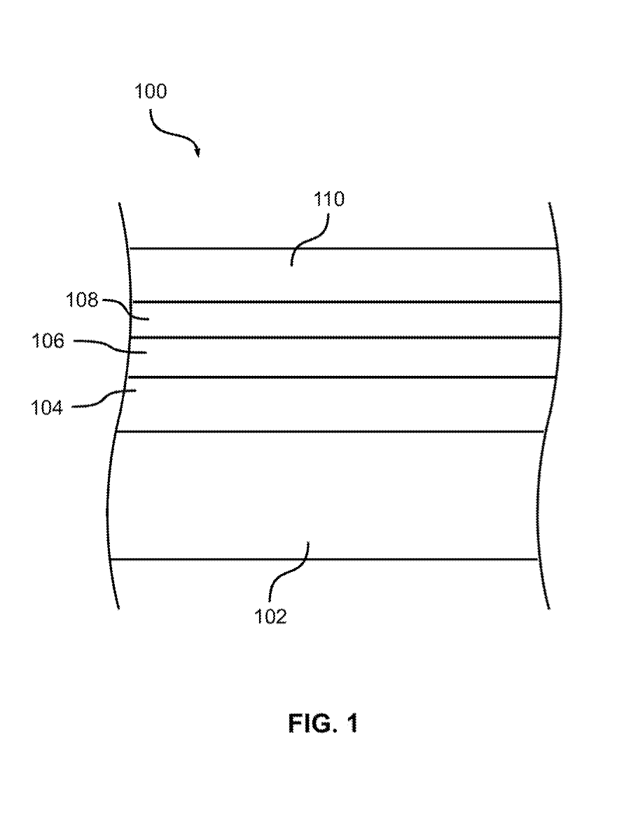

FIG. 1 illustrates a photovoltaic device 100 according to some embodiments. In some embodiments, the photovoltaic device is cadmium telluride-based (i.e., utilizes cadmium telluride in the light-absorbing layer, as described below). In the depicted embodiment, the photovoltaic device includes a substrate 102, a front contact (or contact layer) 104, a window layer 106, a light-absorbing layer 108, and a back contact 110.

The substrate 102 may be transparent. In some embodiments, the substrate 102 is made of a low emissivity glass, such as borosilicate glass or soda lime glass. However, in some embodiments, the transparent substrate 102 may be made of sodium-free glass. In some embodiments, other materials may be used, such as plastic or a transparent polymer, such as polyethylene terephthalate (PET), poly(methyl methacrylate) (PMMA), polycarbonate (PC), and polyimide (PI). The transparent substrate 102 has a thickness of, for example, between about 1 and about 10 millimeters (mm). In a testing environment, the transparent substrate 102 may be round with a diameter of, for example, about 200 or about 300 mm. However, in a manufacturing environment, the transparent substrate 102 may be square or rectangular and significantly larger (e.g., between about 0.5 meters (m) and about 6 m across).

The various layers/components 104-110 of the photovoltaic device 100 may be formed sequentially (i.e., from bottom to top) above the transparent substrate 102 using, for example, physical vapor deposition (PVD) and/or reactive sputtering, DC or AC sputtering, low pressure chemical vapor deposition (CVD), atmospheric pressure CVD, plasma-enhanced chemical vapor deposition (PECVD), thermal chemical vapor deposition, spin-on deposition, and spray-pyrolysis. In some embodiments, the layers/components 104-110 are formed above the entire substrate 102. However, in some embodiments, the layers/components 104-110 may only be formed above isolated portions of the transparent substrate 102.

Although the layers may be described as being formed “above” the previous layer (or the substrate), it should be understood that in some embodiments, each layer is formed directly on (and adjacent to) the previously provided/formed component (e.g., layer). In some embodiments, additional layers may be included between the layers, and other processing steps (e.g., such an annealing/heating processes) may also be performed between the formation of various layers.

Still referring to FIG. 1, the front contact (or front contact layer) 104 is formed above the substrate 102. In some embodiments, the front contact includes a transparent conductive oxide (TCO), such as indium tin oxide (ITO). However, other materials may also be used in the front contact, such as cadmium oxide, indium oxide, gallium oxide, cadmium-indium oxide, indium-tin oxide, zinc oxide, tin oxide, and zinc-tin oxide. Additionally, although the front contact 104 is shown as only one layer, the front contact 104 may include multiple sub-layers (such as a barrier sub-layer), which may include different materials, such as silicon oxide, silicon-aluminum oxide, and cadmium stannate. The front contact 104 may have a thickness of, for example, between about 100 nanometers (nm) and about 500 nm.

The window layer 106 is formed above the front contact 104. In some embodiments, the window layer 106 includes (e.g., is made of) a n-type semiconductor material, and as such, may also be referred to a “n-type junction partner” (or n-type window layer). One exemplary material that can be used in the window layer is cadmium sulfide. The window layer 106 may have a thickness of, for example, between about 50 nm and 100 nm.

The light-absorbing layer (or absorber layer) 108 is formed above the window layer 106. In some embodiments, the light-absorbing layer 108 includes (e.g., is made of) a p-type semiconductor material, and as such, may also be referred to as a “p-type absorber layer.” In some embodiments, the light-absorbing layer includes cadmium telluride. However, in some embodiments, the light-absorbing layer includes copper-indium-gallium-selenide, gallium arsenide, silicon, or a combination thereof. The light-absorbing layer may have a thickness of, for example, between about 20 nm about 100 nm.

Still referring to FIG. 1, the back contact (or back contact layer) 110 is formed above the light absorbing layer 108. In some embodiments, the back contact 110 includes zinc telluride. More specifically, the back contact 110 may include nitrogen-doped zinc telluride. The back contact 110 may have a thickness of, for example, between about 100 nm and about 500 nm.

In accordance with some of the embodiments described herein, the back contact 110 is formed using a PVD deposition process, such as sputtering. In order to achieve the desired nitrogen doping, the deposition is performed utilizing particular processing conditions, such as the processing temperature and the introduction of nitrogen gas into the processing chamber.

Specifically, in some embodiments, the deposition is performed at a temperature of between about 100° C. and about 450° C. Preferably, the temperature is between about 200° C. and about 400° C. More preferably, the temperature is between about 250° C. and about 375° C.

In some embodiments, the deposition is performed in a gaseous environment (e.g., within a PVD processing chamber) that has a concentration (i.e., comprises a volume percentage of nitrogen) of between about 3% and about 10%. Preferably, the nitrogen concentration is between about 3% and about 9%, such as between about 3% and about 9%. More preferably, the nitrogen concentration is between about 3% and about 8%, such as between about 4% and about 8%. In some embodiments, the nitrogen concentration is about 6%.

It should be understood that the processing conditions described separately above (e.g., with respect to processing temperature and nitrogen concentration) may be combined in some embodiments. For example, in some embodiments, the deposition is performed at a temperature of between about 100° C. and about 450° C. in a gaseous environment that comprises between about 3% and about 10% (volume %) nitrogen. As another, more specific example, in some embodiments, the deposition is performed at a temperature of between about 200° C. and about 400° C. in a gaseous environment that comprises between about 3% and about 9% (volume %) nitrogen. As yet a further, even more specific example, in some embodiments, the deposition is performed at a temperature of between about 250° C. and about 375° C. in a gaseous environment that comprises between about 4% and about 8% (volume %) nitrogen.

The deposition of the back contact 110 may substantially complete the formation of the photovoltaic device 100. However, in some embodiments, additional components may also be provided to/formed on the photovoltaic device 100, such as contact terminals for the front contact 104 and the back contact 110 and a glass backing layer positioned above the back contact 110.

As will be understood by one skilled in the art, a p-n junction is formed at the interface between the window layer 106 and the light-absorbing layer 108. When the photovoltaic device 100 is exposed to sunlight, photons are absorbed at the p-n junction, which results in the creation of photo-generated electron-hole pairs. Movement of the electron-hole pairs is influenced by a built-in electric field, which produces current flow. The current flow occurs between a first terminal that is electrically connected to the front contact 104 and a second terminal that is electrically connected to the back contact 110.

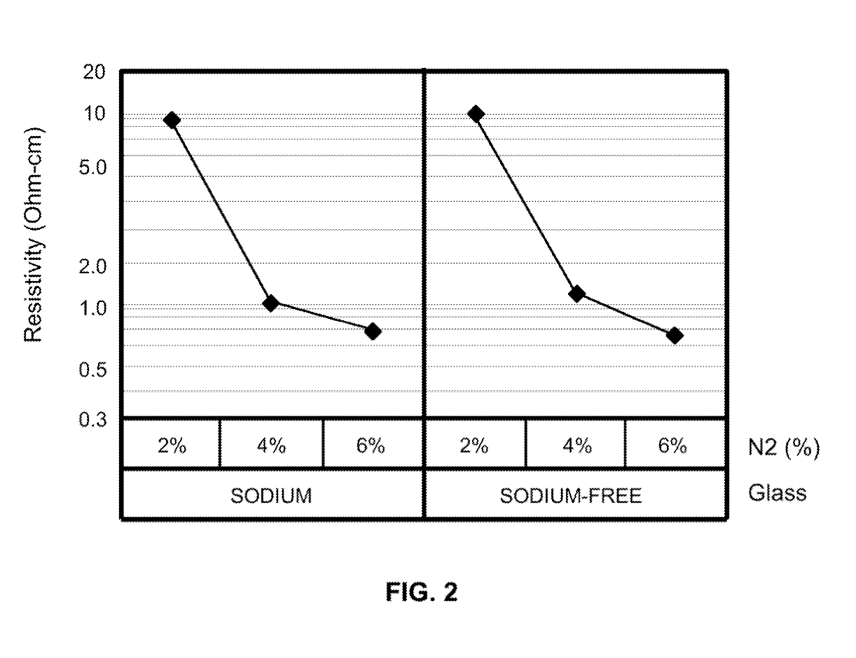

FIG. 2 graphically illustrates the resistivity (Ohm-cm) of zinc telluride formed in accordance with some embodiments described herein. In particular, the left side of the graph in FIG. 2 depicts the resistivity of zinc telluride sputtered at a given temperature (e.g., about 300° C.) onto a sodium-containing glass substrate in gaseous environments of 2%, 4%, and 6% (volume %) nitrogen, while the right side of the graph depicts the same sputtered onto a sodium-free glass substrate. As shown, the resistivity decreases as the nitrogen concentration is increased up to 6% (volume %) for deposition on both sodium-containing and sodium-free glass substrates, down to about 0.633 Ohm-cm.

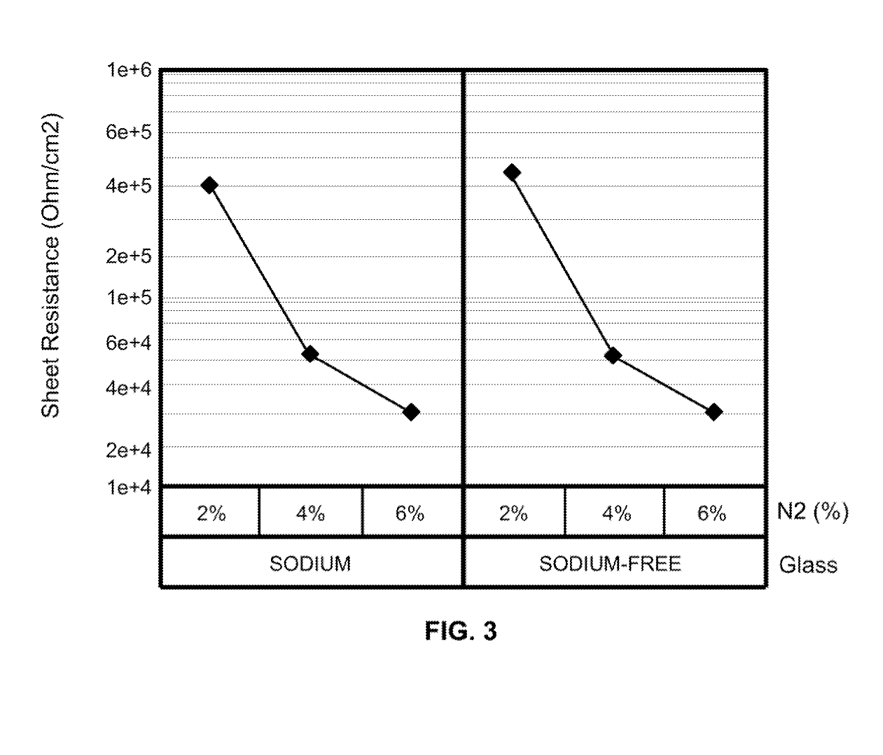

FIG. 3 graphically illustrates the sheet resistance (Ohm/square) of zinc telluride formed in accordance with some embodiments described herein. In particular, the left side of the graph in FIG. 2 depicts the sheet resistance of zinc telluride sputtered at a given temperature (e.g., about 300° C.) onto a sodium-containing glass substrate in gaseous environments of 2%, 4%, and 6% (volume %) nitrogen, while the right side of the graph depicts the same sputtered onto a sodium-free glass substrate. As shown, the sheet resistance decreases as the nitrogen concentration is increased up to 6% (volume %) for deposition on both sodium-containing and sodium-free glass substrates.

Using Hall Effect measurements, the carrier density of the nitrogen-doped zinc telluride formed in accordance with some embodiments (e.g., zinc telluride formed on sodium-free glass at about 300° C. in with a nitrogen concentration of 6% (volume %)) was found to be between 1.93×10¹⁹ cm⁻³ and 2.03×10¹⁹ cm⁻³. The electron mobility was found to be between 0.487 cm²/V s and 0.509 cm²/V s. The resistivity was found to be between 0.633 Ohm-cm and 0.636 Ohm-cm.

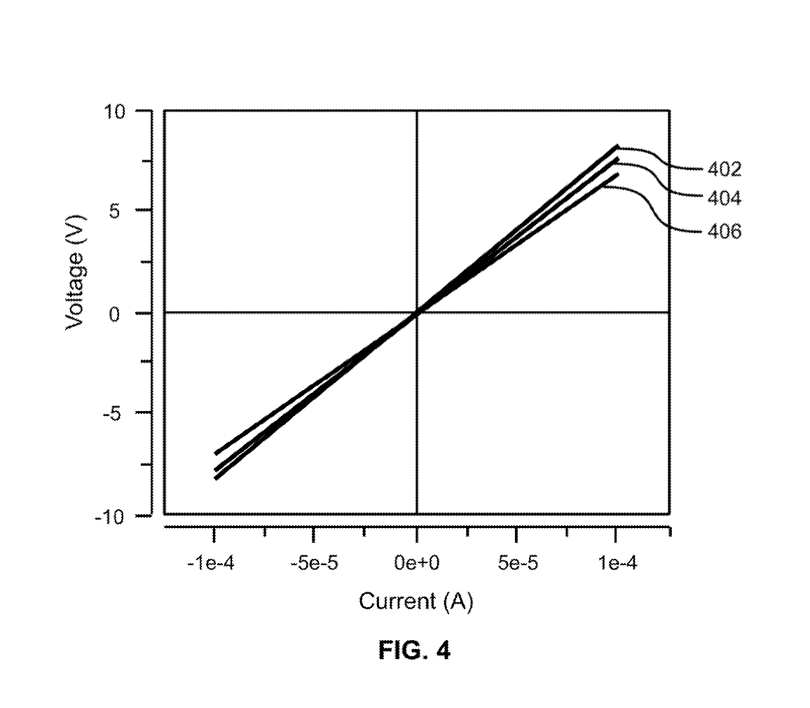

FIG. 4 graphically illustrates the current-voltage dependence (i.e., with amperage (A) on the x-axis and voltage (V) on the y-axis) of zinc telluride formed in various gaseous environments (e.g., at about 300° C.). In particular, line 402 depicts the current-voltage dependence of zinc telluride formed in a gaseous environment with a nitrogen concentration of 0% (volume %). Line 404 depicts the current-voltage dependence of zinc telluride formed in a gaseous environment with a nitrogen concentration of 8% (volume %). Line 406 depicts the current-voltage dependence of zinc telluride formed in a gaseous environment with a nitrogen concentration of 6% (volume %). As is indicated in FIG. 4, the change in voltage is less dependent on changes in current for zinc telluride formed in a gaseous environment of 6% (volume %) nitrogen than it is for zinc telluride formed in gaseous environments of 0% and 8% (volume %) nitrogen (i.e., with respect to FIG. 4, the slope of line 406 is less than the slopes of lines 402 and 404).

The experimental data described above indicates that nitrogen-doped zinc telluride formed in accordance with some embodiments described herein provides suitably low resistivity (and/or high carrier concentration) for use as a back contact in cadmium telluride-based photovoltaic devices. Additionally, because copper is not used at the dopant, back contacts using the nitrogen-doped zinc telluride may provide improved long-term stability and reliability (i.e., when compared to those using copper as the dopant).

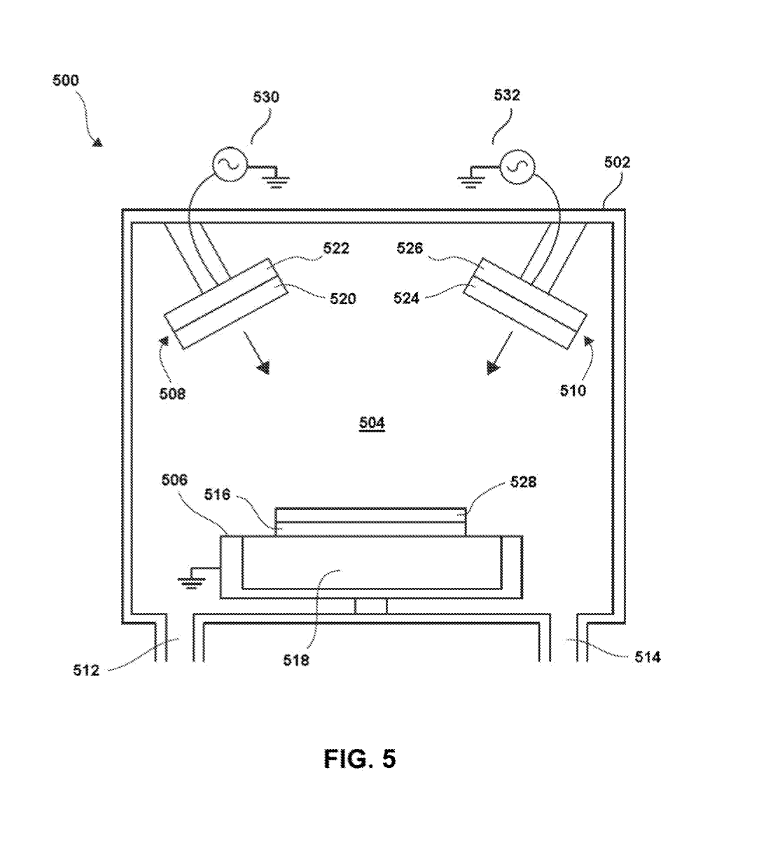

FIG. 5 provides a simplified illustration of a physical vapor deposition (PVD) tool (and/or system) 500 which may be used, in some embodiments, to form nitrogen-doped zinc telluride (and/or at least some components of a photovoltaic device, such as a zinc telluride back contact, as described above). The PVD tool 500 shown in FIG. 5 includes a housing 502 that defines, or encloses, a processing chamber 504, a substrate support 506, a first target assembly 508, and a second target assembly 510.

The housing 502 includes a gas inlet 512 and a gas outlet 514 near a lower region thereof on opposing sides of the substrate support 506. The substrate support 506 is positioned near the lower region of the housing 502 and in configured to support a substrate 516. The substrate 516 may be a round substrate having a diameter of, for example, about 200 mm or about 300 mm. In other embodiments (such as in a manufacturing environment), the substrate 516 may have other shapes, such as square or rectangular, and may be significantly larger (e.g., about 0.5-about 6 m across). The substrate support 506 includes a support electrode 518 and is held at ground potential during processing, as indicated.

The first and second target assemblies (or process heads) 508 and 510 are suspended from an upper region of the housing 502 within the processing chamber 504. The first target assembly 508 includes a first target 520 and a first target electrode 522, and the second target assembly 510 includes a second target 524 and a second target electrode 526. As shown, the first target 520 and the second target 524 are oriented or directed towards the substrate 516. As is commonly understood, the first target 520 and the second target 524 include one or more materials that are to be used to deposit a layer of material 528 on the upper surface of the substrate 516.

The materials used in the targets 520 and 524 may, for example, include zinc, tellurium, indium, gallium, tin, tin, magnesium, aluminum, lanthanum, yttrium, titanium, antimony, strontium, bismuth, silicon, silver, nickel, chromium, niobium, any other material(s) described above, or any combination thereof (i.e., a single target may be made of an alloy of several metals). Additionally, the materials used in the targets may include oxygen, nitrogen, or a combination of oxygen and nitrogen in order to form oxides, nitrides, and oxynitrides. Additionally, although only two targets 520 and 524 are shown, additional targets may be used.

The PVD tool 500 also includes a first power supply 530 coupled to the first target electrode 522 and a second power supply 532 coupled to the second target electrode 524. As is commonly understood, in some embodiments, the power supplies 530 and 532 pulse direct current (DC) power to the respective electrodes, causing material to be, at least in some embodiments, simultaneously sputtered (i.e., co-sputtered) from the first and second targets 520 and 524. In some embodiments, the power is alternating current (AC) to assist in directing the ejected material towards the substrate 516.

During sputtering, inert gases (or a plasma species), such as argon or krypton, may be introduced into the processing chamber 504 through the gas inlet 512, while a vacuum is applied to the gas outlet 514. The inert gas(es) may be used to impact the targets 520 and 524 and eject material therefrom, as is commonly understood. In embodiments in which reactive sputtering is used, reactive gases, such as oxygen and/or nitrogen, may also be introduced, which interact with particles ejected from the targets (i.e., to form oxides, nitrides, and/or oxynitrides).

Although not shown in FIG. 5, the PVD tool 500 may also include a control system having, for example, a processor and a memory, which is in operable communication with the other components shown in FIG. 5 and configured to control the operation thereof in order to perform the methods described herein.

Although the PVD tool 500 shown in FIG. 5 includes a stationary substrate support 506, it should be understood that in a manufacturing environment, the substrate 516 may be in motion (e.g., an in-line configuration) during the formation of various layers described herein.

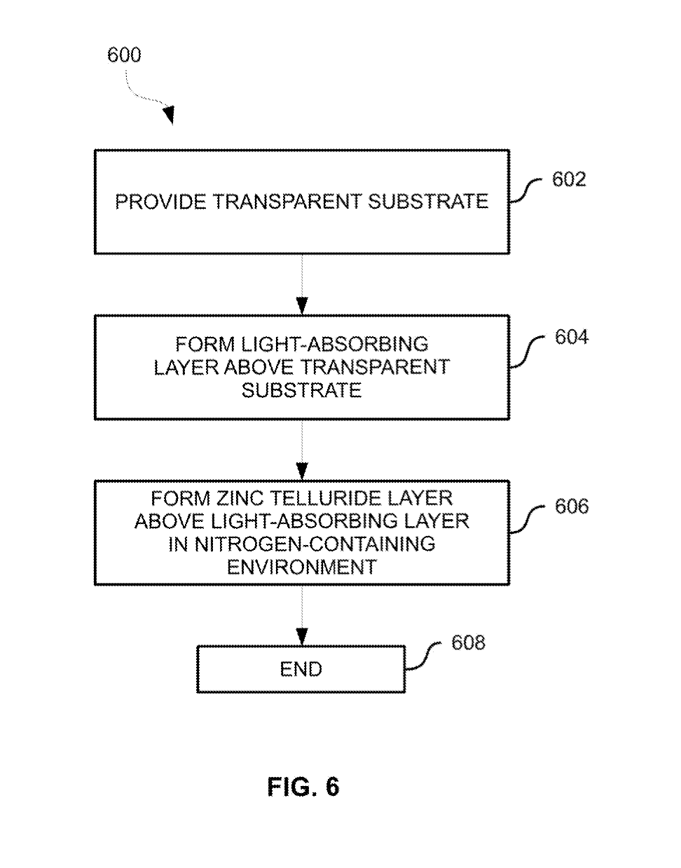

FIG. 6 is a flow chart illustrating a method 600 for forming a photovoltaic device (or more generally, for forming nitrogen-doped zinc telluride) according to some embodiments. The method 600 begins at block 602 by providing a transparent substrate, such as the examples described above (e.g., glass).

At block 604, a light-absorbing layer is formed above the transparent substrate. In some embodiments, the light-absorbing layer includes cadmium telluride, copper-indium-gallium-selenide, gallium arsenide, silicon, or a combination thereof

At block 606, a zinc telluride layer is formed above the light-absorbing layer. In some embodiments, the zinc telluride layer is formed using PVD (e.g., sputtering) performed under particular processing conditions. Specifically, in some embodiments, the deposition is performed at a temperature of between about 100° C. and about 450° C. Preferably, the temperature is between about 200° C. and about 400° C. More preferably, the temperature is between about 250° C. and about 375° C. In some embodiments, the deposition is performed in a gaseous environment (e.g., within the PVD processing chamber) that has a nitrogen concentration (i.e., comprises a volume percentage of nitrogen) of between about 3% and about 10%. Preferably, the nitrogen concentration is between about 3% and about 9% (volume %). More preferable, the nitrogen concentration is between about 3% and about 8% (or between about 4% and about 8%) (volume %). In some embodiments, the nitrogen concentration is about 6% (volume %).

In some embodiments, the zinc telluride layer is utilized at a back contact for a photovoltaic device. As such, although not shown, block 606 (or the method 600 as a whole) may include the formation of additional components of a photovoltaic device, such as a front contact and a window low, as described above. At block 608, the method ends.

Thus, in some embodiments, a method for forming a photovoltaic device is provided. A transparent substrate is provided. A light-absorbing layer is formed above the transparent substrate. A nitrogen-doped zinc telluride layer is formed above the light-absorbing layer. The nitrogen-doped zinc telluride layer is formed using PVD at a processing temperature of between about 100° C. and about 450° C. in a gaseous environment that includes between about 3% and about 10% (volume %) nitrogen gas.

In some embodiments, a method for forming a photovoltaic device is provided. A transparent substrate is provided. A front contact is formed above the transparent substrate. The front contact includes a transparent conductive oxide. A light-absorbing layer is formed above the front contact. The light absorbing layer includes cadmium telluride. A back contact is formed above the light-absorbing layer. The back contact includes nitrogen-doped zinc telluride. The nitrogen-doped zinc telluride is formed using PVD at a processing temperature of between about 100° C. and about 450° C. in a gaseous environment that includes between about 3% and about 10% (volume %) nitrogen gas.

In some embodiments, a method for forming a photovoltaic device is provided. A glass substrate is provided. A front contact is formed above the glass substrate. The front contact includes a transparent conductive oxide. A light-absorbing layer is formed above the front contact. The light absorbing layer includes cadmium telluride. A back contact is formed above the light-absorbing layer. The back contact includes nitrogen-doped zinc telluride. The nitrogen-doped zinc telluride is formed using PVD at a processing temperature of between about 100° C. and about 450° C. in a gaseous environment that includes between about 3% and about 10% (volume %) nitrogen gas.

In some embodiments, a method for forming nitrogen-doped zinc telluride is provided. The nitrogen-doped zinc telluride is formed using PVD at a processing temperature of between about 100° C. and about 450° C. in a gaseous environment that includes between about 3% and about 10% (volume %) nitrogen gas.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A method for forming a photovoltaic device, the method comprising:
providing a transparent substrate;
forming a light-absorbing layer above the transparent substrate; and
forming a nitrogen-doped zinc telluride layer above the light-absorbing layer, wherein the nitrogen-doped zinc telluride layer is formed using physical vapor deposition (PVD) in a gaseous environment comprising between about 3% and about 10% by volume of nitrogen gas.

2. The method of claim 1, wherein the light-absorbing layer comprises cadmium telluride.

3. The method of claim 2, wherein the PVD processing temperature is between about 200° C. and about 400° C.

4. The method of claim 3, wherein the PVD processing temperature is between about 250° C. and about 375° C.

5. The method of claim 2, wherein the gaseous environment comprises between about 3% and about 9% by volume of nitrogen gas.

6. The method of claim 5, wherein the gaseous environment comprises between about 3% and about 8% by volume of nitrogen gas.

7. The method of claim 2, wherein the nitrogen-doped zinc telluride layer forms a back contact, and further comprising forming a front contact above the transparent substrate, the front contact comprising a transparent conductive oxide, wherein the light-absorbing layer is formed above the front contact.

8. The method of claim 7, wherein the transparent conductive oxide comprises indium-tin oxide.

9. The method of claim 8, further comprising forming a window layer above the front contact, the window layer comprising cadmium sulfide, wherein the light-absorbing layer is formed above window layer.

10. The method of claim 9, wherein the transparent substrate comprises glass.

11. A method for forming a photovoltaic device, the method comprising:
providing a transparent substrate;
forming a front contact above the transparent substrate, wherein the front contact comprises a transparent conductive oxide;
forming a light-absorbing layer above the front contact, wherein the light absorbing layer comprises cadmium telluride; and
forming a back contact above the light-absorbing layer, the back contact comprising nitrogen-doped zinc telluride, wherein the nitrogen-doped zinc telluride is formed using physical vapor deposition (PVD) at a processing temperature of between about 100° C. and about 450° C. in a gaseous environment comprising between about 3% and about 10% by volume of nitrogen gas.

12. The method of claim 11, wherein the PVD processing temperature is between about 200° C. and about 400° C.

13. The method of claim 12, wherein the PVD processing temperature is between about 250° C. and about 375° C.

14. The method of claim 11, wherein the gaseous environment comprises between about 3% and about 9% by volume of nitrogen gas.

15. The method of claim 14, wherein the gaseous environment comprises between about 3% and about 8% by volume of nitrogen gas.

16. A method for forming a photovoltaic device, the method comprising:
providing a glass substrate;
forming a front contact above the glass substrate, wherein the front contact comprises a transparent conductive oxide;
forming a light-absorbing layer above the front contact, wherein the light absorbing layer comprises cadmium telluride; and
forming a back contact above the light-absorbing layer, the back contact comprising nitrogen-doped zinc telluride, wherein the nitrogen-doped zinc telluride is formed using physical vapor deposition (PVD) at a processing temperature of between about 100° C. and about 450° C. in a gaseous environment comprises between about 3% and about 10% by volume of nitrogen gas.

17. The method of claim 16, wherein the PVD processing temperature is between about 200° C. and about 400° C.

18. The method of claim 17, wherein the gaseous environment comprises between about 3% and about 9% by volume of nitrogen gas.

19. The method of claim 18, wherein the PVD processing temperature is between about 250° C. and about 375° C.

20. The method of claim 19, wherein the gaseous environment comprises between about 3% and about 8% by volume of nitrogen gas.
